(19) United States
(12) Patent Application Publication
(10) Pub. No.: US 2026/0329138 A1
(43) Pub. Date: Oct. 22, 2026

(54) DISPLAY PANEL, TILED DISPLAY DEVICE AND VEHICLE DISPLAY APPARATUS

(71) Applicant: AUO Corporation, Hsinchu City (TW)

(72) Inventors: Chia-Jung Wu, Hsinchu City (TW); Yueh-Chi Wu, Hsinchu City (TW); Ti-Kuei Yu, Hsinchu City (TW); Ya-Ling Hsu, Hsinchu City (TW)

(73) Assignee: AUO Corporation, Hsinchu City (TW)

(21) Appl. No.: 19/313,854

(22) Filed: Aug. 28, 2025

(30) Foreign Application Priority Data
Apr. 18, 2025 (TW) 114114731

(51) Int. Cl. G02F 1/1362; H10H 29/49; H10K 59/131; H10K 59/18

(52) U.S. Cl. CPC G02F 1/136286; H10H 29/49; H10K 59/1315; H10K 59/18

(57) ABSTRACT

A display panel, having a first display area and a second display area adjacent to the first display area, and including first display units, a first scan line, a first data line, second display units, a second scan line and a second data line. The first display units are disposed in the first display area. Both the first scan line and the first data line are disposed in the first display area and electrically connected to the first display units. The second display units are disposed in the second display area. The second scan line is disposed in the second display area and electrically connected to the second display units. The second data line is disposed in the first display area and the second display area and electrically connected to the second display units.

### CROSS-REFERENCE TO RELATED APPLICATION

This application claims the priority benefit of Taiwan application serial no. 114114731, filed on Apr. 18, 2025. The entirety of the above-mentioned patent application is hereby incorporated by reference herein and made a part of this specification.

### BACKGROUND

### Technical Field

The disclosure relates to a photoelectric device, and more particularly to a display panel, a tiled display device including the display panel, and a vehicle display apparatus including the display panel or the tiled display device.

### Description of Related Art

Currently, the panel sizes that can be mass-produced by panel manufacturers are still limited. The main reason is that as the size of the panel increases, the cost increases significantly and the yield decreases, making it difficult to improve the economic benefit of directly fabricating large-size panels. Therefore, assembling small-size panels into a large panel is currently a relatively feasible way to realize a large-size panel.

However, although the bezel of the panel has been greatly reduced through various improvement technologies, the bezel between the panels can still be seen when the panels are tiled, resulting in an interrupted image that affects the display effect. Therefore, how to enable the tiled display to achieve a seamless display effect is still one of the goals that related industries are actively seeking to improve.

### SUMMARY

An embodiment of the disclosure provides a display panel, having a first display area and a second display area adjacent to the first display area, and including a plurality of first display units, a first scan line, a first data line, a plurality of second display units, a second scan line, and a second data line. The plurality of first display units are disposed in the first display area. The first scan line is disposed in the first display area and electrically connected to the plurality of first display units. The first data line is disposed in the first display area and electrically connected to the plurality of first display units. The plurality of second display units are disposed in the second display area. The second scan line is disposed in the second display area and electrically connected to the plurality of second display units. The second data line is disposed in the first display area and the second display area and electrically connected to the plurality of second display units.

In an embodiment of the disclosure, the plurality of first display units are a plurality of liquid crystal display units or a plurality of organic light-emitting diode display units.

In an embodiment of the disclosure, the plurality of second display units are a plurality of micro light-emitting diode display units.

In an embodiment of the disclosure, the display panel includes a plurality of first scan lines. The plurality of first scan lines extend along a first direction and are arranged along a second direction. The second direction intersects the first direction.

In an embodiment of the disclosure, the display panel includes a plurality of first data lines. The plurality of first data lines extend along the second direction and are arranged along the first direction.

In an embodiment of the disclosure, the display panel includes a plurality of second scan lines. The plurality of second scan lines extend along the first direction and are arranged along the second direction.

In an embodiment of the disclosure, the display panel includes a plurality of second data lines. The plurality of second data lines extend along the second direction and are arranged along the first direction.

In an embodiment of the disclosure, the display panel further includes a shielding line. The shielding line is disposed between the first data line and the second data line.

In an embodiment of the disclosure, the shielding line is disposed only in the first display area, and the shielding line is a common electrode line for the plurality of first display units.

In an embodiment of the disclosure, the shielding line is disposed in the first display area and the second display area, and the shielding line is a power signal line for the plurality of second display units.

In an embodiment of the disclosure, the power signal line includes at least one of a system high voltage signal line, a system voltage signal line, and a system reference voltage signal line.

In an embodiment of the disclosure, the power signal line includes the system high voltage signal line and the system voltage signal line, and the system high voltage signal line and the system voltage signal line are alternately arranged along the first direction.

In an embodiment of the disclosure, the system high voltage signal line and the system voltage signal line overlap a same one of the plurality of first data lines.

In an embodiment of the disclosure, the system high voltage signal line and the system voltage signal line overlap different ones of the plurality of first data lines.

In an embodiment of the disclosure, the display panel further includes a sealant. The sealant is disposed in the second display area and covers a portion of the plurality of second display units.

In an embodiment of the disclosure, the display panel further includes a gate driving element. The gate driving element is disposed in the second display area and electrically connected to the first scan line and the second scan line.

In an embodiment of the disclosure, the display panel further includes a first chip bonding member and a second chip bonding member. The first chip bonding member and the second chip bonding member are disposed in a peripheral area of the display panel and respectively electrically connected to the first data line and the second data line.

An embodiment of the disclosure provides a tiled display device, including two adjacent display panels described above.

An embodiment of the disclosure provides a vehicle display apparatus, including the display panel described above or the tiled display device described above.

In an embodiment of the disclosure, the vehicle display apparatus has a display screen with a strip-shaped or T-shaped profile.

To make the features and advantages of the disclosure more comprehensible, several embodiments accompanied with drawings are described in detail as follows.

### BRIEF DESCRIPTION OF THE DRAWINGS

FIG. 1 is a top schematic view of a display device according to an embodiment of the disclosure.

FIG. 2 is a partially enlarged schematic view of a region I of FIG. 1.

FIG. 3 is a cross-sectional schematic view taken along a section line A-A′ of FIG. 2.

FIG. 4 is a partially enlarged schematic view of a region II of FIG. 2.

FIG. 5 is a partially enlarged schematic view of a region III of FIG. 4.

FIG. 6 is a cross-sectional schematic view taken along a section line B-B′ of FIG. 5.

FIG. 7 is a cross-sectional schematic view of a display device according to an embodiment of the disclosure.

FIG. 8 is a cross-sectional schematic view of a display device according to an embodiment of the disclosure.

FIG. 9 is a cross-sectional schematic view of a display device according to an embodiment of the disclosure.

### DESCRIPTION OF THE EMBODIMENTS

In the drawings, for clarity, the thicknesses of layers, films, panels, and regions are exaggerated. Throughout the specification, the same reference numerals indicate the same elements. It is understood that when an element such as a layer, film, region, or substrate is referred to as being “on” another element or “connected to” another element, it can be directly on or connected to the other element, or intermediate elements may also be present. In contrast, when an element is referred to as being “directly on” or “directly connected to” another element, no intermediate elements are present. As used herein, “connected” may refer to physical and/or electrical connection. Furthermore, “electrically connected” or “coupled” may include the presence of other elements between two elements.

It is understood that although the terms “first,” “second,” “third,” etc. may be used herein to describe various elements, components, regions, layers, and/or portions, these elements, components, regions, layers, and/or portions should not be limited by these terms. These terms are only used to distinguish one element, component, region, layer, or portion from another element, component, region, layer, or portion. Thus, a first “element,” “component,” “region,” “layer,” or “portion” discussed below may be termed a second element, component, region, layer, or portion without departing from the teachings herein.

The terminology used herein is for the purpose of describing particular embodiments only and is not intended to be limiting. As used herein, unless the context clearly indicates otherwise, the singular forms “a,” “an,” and “the” are intended to include the plural forms as well, including “at least one” or meaning “and/or.” As used herein, the term “and/or” includes any and all combinations of one or more of the associated listed items. It is also understood that when the terms “comprise” and/or “include” are used in the specification, they specify the presence of the stated features, regions, integers, steps, operations, elements, and/or components, but do not preclude the presence or addition of one or more other features, regions, integers, steps, operations, elements, components, and/or combinations thereof.

In addition, relative terms such as “lower” or “bottom” and “upper” or “top” may be used herein to describe the relationship of one element to another element as illustrated in the figures. It is understood that the relative terms are intended to include orientations of the device other than those depicted in the figures. For example, if the device in one of the figures is turned over, the element described as being on the “lower” side of another element would be oriented on the “upper” side of the other element. Thus, the exemplary term “lower” may include both “lower” and “upper” orientations, depending on the specific orientation of the figure. Similarly, if the device in one of the figures is turned over, the element described as being “under” or “beneath” another element would be oriented as “above” the other element. Thus, the exemplary terms “under” or “beneath” may include both upper and lower orientations.

In consideration of the specific quantities of the measurements discussed and the measurement-related errors (i.e., limitations of the measurement system), the terms “about,” “approximately,” or “substantially” as used herein include the stated value and the average value within an acceptable deviation range of the specific value determined by a person having ordinary skill in the art. For example, “about” may mean within one or more standard deviations of the stated value, or within ±30%, ±20%, ±10%, or ±5%. Furthermore, the terms “about,” “approximately,” or “substantially” as used herein may be selected according to optical properties, etching properties, or other properties, to use a more acceptable deviation range or standard deviation, and a single standard deviation does not need to apply to all properties.

Unless otherwise defined, all terms (including technical and scientific terms) as used herein have the same meaning as commonly understood by a person having ordinary skill in the art to which the disclosure pertains. It will be further understood that terms such as those defined in commonly used dictionaries should be interpreted as having a meaning that is consistent with their meaning in the relevant technology and in the context of the disclosure, and should not be interpreted in an idealized or overly formal sense unless expressly so defined herein.

Cross-sectional views of schematic diagrams referenced herein are used to describe exemplary embodiments as idealized embodiments. Therefore, variations in shapes shown in the figures as a result of, for example, manufacturing technology and/or tolerances can be expected. Accordingly, the embodiments described herein should not be construed as being limited to the specific shapes of regions illustrated herein but rather include shape deviations caused by manufacturing, for example. For example, a region shown or described as flat may generally have rough and/or nonlinear characteristics. In addition, the illustrated sharp angles may be rounded. Therefore, the regions shown in the drawings are essentially schematic, and their shapes are not intended to illustrate the exact shapes of the regions and are not intended to limit the scope of the claims.

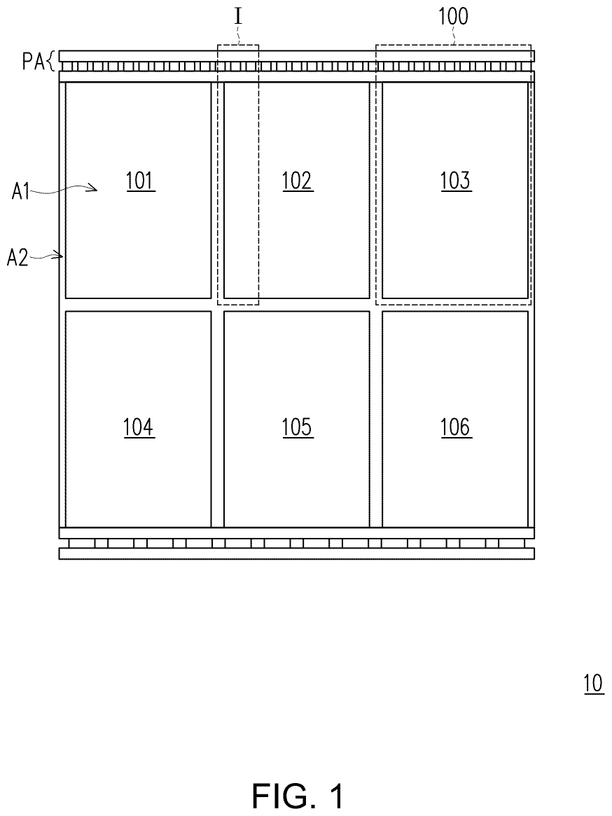

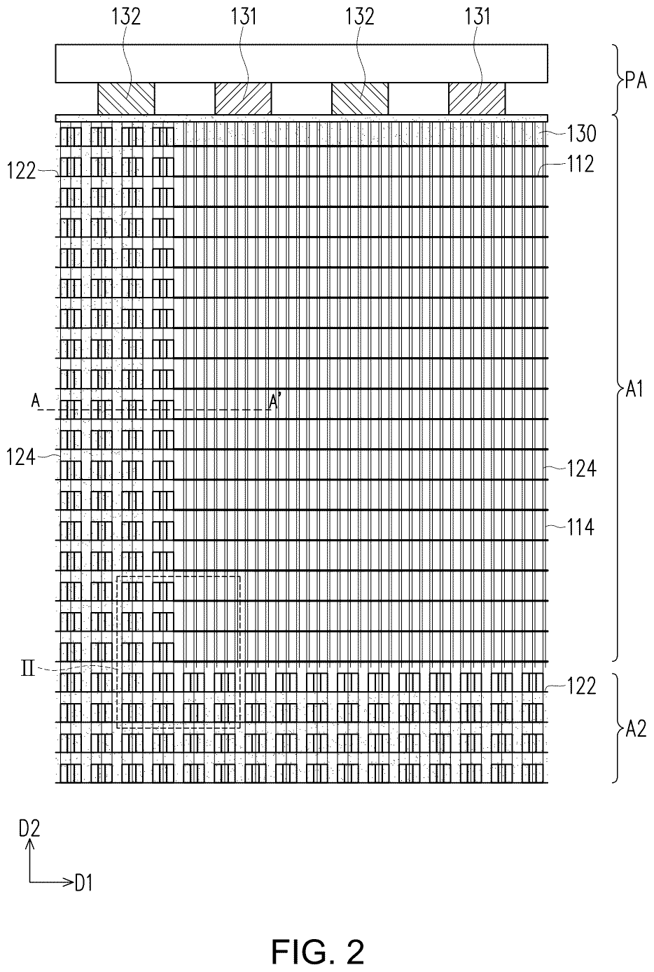

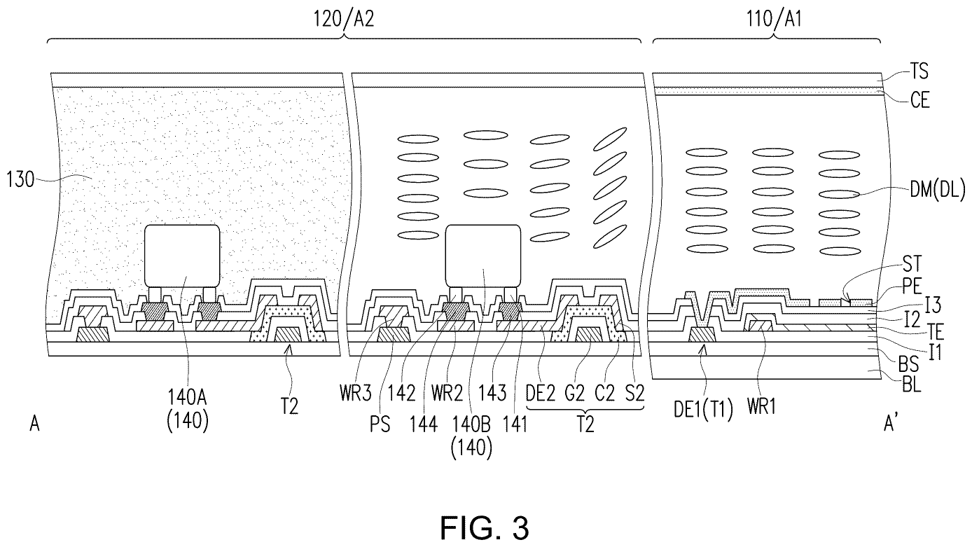

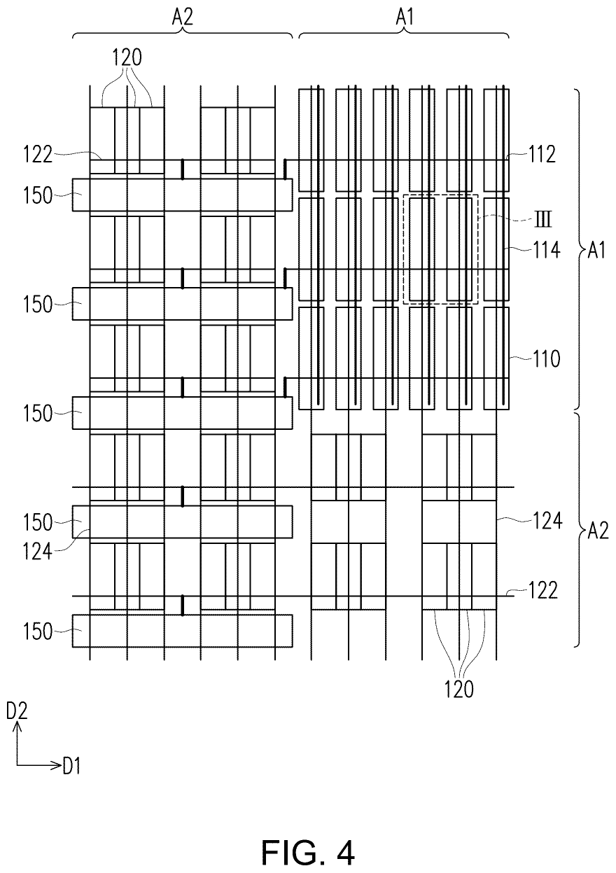

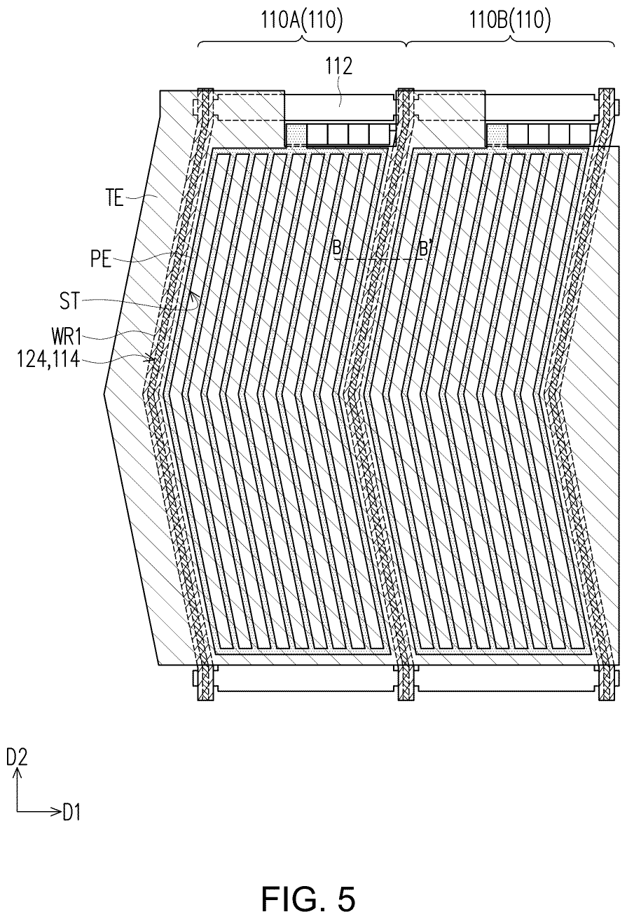

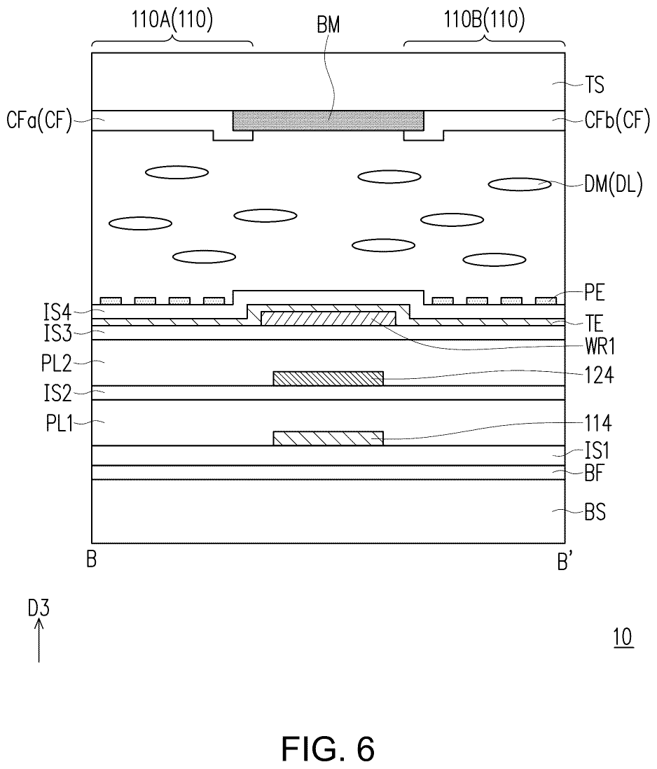

FIG. 1 is a top schematic view of a display device 10 according to an embodiment of the disclosure. FIG. 2 is a partially enlarged schematic view of a region I of FIG. 1. FIG. 3 is a cross-sectional schematic view taken along a section line A-A′ of FIG. 2. FIG. 4 is a partially enlarged schematic view of a region II of FIG. 2. FIG. 5 is a partially enlarged schematic view of a region III of FIG. 4. FIG. 6 is a cross-sectional schematic view taken along a section line B-B′ of FIG. 5. For clarity of illustration, some components shown in other figures may be omitted from various drawings. For example, FIG. 3 omits a color filter structure CF and a black matrix structure BM shown in FIG. 6, and FIG. 4 omits a sealant 130 shown in FIG. 2. Hereinafter, the implementation manner of each element of the display device 10 will be described in conjunction with the drawings, but the disclosure is not limited thereto.

Please refer to FIG. 1. The display device 10 may be a tiled display device. For example, the display device 10 includes a plurality of display panels 100. The plurality of display panels 100 are joined edge-to-edge to form the display device 10 by tiling. The display panel 100 may have a display area A1 and a display area A2 that are adjacent. The display area A1 is, for example, a main display area of the display panel 100, and the display area A2 is, for example, a peripheral display area of the display panel 100. The display area A2 may be disposed along a side of the display area A1. For example, when the display panel 100 is a liquid crystal display panel, the display area A2 may include a region where a sealant is disposed. In some embodiments, the display area A2 surrounds the display area A1, and the display areas A2 of adjacent display panels 100 may form a tiled display area A2 through tiling. In some embodiments, the display area A1 has a rectangular profile, and the display area A2 may be located at three sides of the display area A1.

The number of the display panels 100 included in the display device 10 is not particularly limited, and the number of the display panels 100 may be determined according to actual usage requirements. In some embodiments, the display device 10 includes 2×2 display panels 100. In some embodiments, the display device 10 includes 3×2 display panels 100, such as display panels 101 to 106 shown in FIG. 1. In some embodiments, the display device 10 includes only the display panels 101 to 103, that is, the display device 10 may have a display screen with a strip-shaped profile. In some embodiments, the display device 10 includes the display panels 101 to 103 and the display panel 105, but does not include the display panel 104 and the display panel 106, that is, the display device 10 may have a display screen with a T-shaped profile. For example, the display device 10 may be used as a vehicle display, in which, for example, the display panel 101 may serve as a virtual digital instrument cluster for a main driver seat of a vehicle, and the display panels 102 to 103 and the display panel 105 may serve as a center console screen for a front passenger seat.

The display panel 100 may further have a peripheral area PA. The peripheral area PA may also be regarded as the peripheral area PA of the display device 10. Driving elements or control elements required by the display panel 100 or the display device 10 may be disposed in the peripheral area PA. For example, please refer to FIG. 2. The display panel 100 may include a chip bonding member 131 and a chip bonding member 132 located in the peripheral area PA. The chip bonding member 131 may provide a driving signal to the display area A1. The chip bonding member 132 may provide a driving signal to the display area A2. The number and arrangement of the chip bonding member 131 and the chip bonding member 132 are not particularly limited and may vary according to the size and layout type of the display panel 100 or the display device 10.

Please refer to FIGS. 3 and 4. In the display area A1, the display panel 100 may include a plurality of display units 110. The display area A1 is, for example, a region where the display units 110 are located. The plurality of display units 110 may be arranged in an array. The display unit 110 may be a sub-pixel in the display area A1 of the display panel 100. In some embodiments, the display unit 110 is a liquid crystal display (LCD) unit, but is not limited thereto. In other embodiments, the display unit 110 may be an organic light-emitting diode (OLED) display unit. In certain embodiments, the display unit 110 may be a display unit using other suitable display technologies.

For example, please refer to FIGS. 3 to 5. When the display unit 110 is a liquid crystal display unit, the display panel 100 may include a lower substrate BS, an upper substrate TS, a display medium layer DL, and a sealant 130. The upper substrate TS may overlap the lower substrate BS. The display medium layer DL may be located between the lower substrate BS and the upper substrate TS. The sealant 130 may be located in the display area A2.

In some embodiments, the lower substrate BS may be a transparent substrate or an opaque substrate. The material thereof may be quartz, glass, a polymer (for example, polyimide (PI)), or other suitable materials. Other elements required by the display device 10, such as light-emitting elements, switching elements, driving elements, and so on, may be carried on the lower substrate BS. The upper substrate TS may be disposed face-to-face opposite to the lower substrate BS, and a substantially uniform spacing may be maintained between the upper substrate TS and the lower substrate BS. Generally, the upper substrate TS may be a transparent substrate, and the material thereof may be, for example, glass, a polymer, or other suitable materials. The lower substrate BS and the upper substrate TS may have the same or different materials. In some embodiments, the lower substrate BS and/or the upper substrate TS may be a flexible substrate.

As shown in FIGS. 2 and 3, the sealant 130 may seal the space between the lower substrate BS and the upper substrate TS along the edges of the lower substrate BS and the upper substrate TS, such that the display medium layer DL is enclosed in the space sealed by the upper substrate TS, the lower substrate BS, and the sealant 130, so as to prevent display medium molecules DM in the display medium layer DL from leaking. The display medium layer DL may mainly be located in the display area A1. In some embodiments, the display medium layer DL may be located in a portion of the display area A2. The material of the sealant 130 may include at least one of polyurethane acrylate (PUA), epoxy acrylate, and silicone, but is not limited thereto.

In the display area A1, the display device 10 may further include a transistor T1, a pixel electrode PE, and a transparent electrode TE disposed corresponding to the display unit 110. The pixel electrode PE is, for example, electrically connected to a drain DE1 of the transistor T1. By controlling the transistor T1 to be turned on or off, a signal can be transmitted to the pixel electrode PE through the drain DE1 of the transistor T1. The pixel electrode PE may be located between the lower substrate BS and the display medium layer DL, or between the upper substrate TS and the display medium layer DL. The transparent electrode TE may be located between the pixel electrode PE and the lower substrate BS. In some embodiments, the material of the pixel electrode PE may include a transparent conductive material. In some embodiments, the drain DE1 of the transistor T1 is located between the pixel electrode PE and the lower substrate BS. In some embodiments, the pixel electrode PE has a plurality of slits ST.

The transparent electrode TE may be disposed corresponding to the pixel electrode PE. In some embodiments, the transparent electrode TE is a transparent planar electrode. The transparent electrode TE may receive a signal through, for example, a wire WR1. An electric field formed by the pixel electrode PE and the transparent electrode TE can drive the display medium molecules DM located in the display area A2 of the display medium layer DL to rotate. In some embodiments, the state of the display medium molecules DM can be changed by the magnitude of the applied electric field and the speed at which the electric field is removed.

In some embodiments, the display panel 100 further includes a counter electrode CE. The counter electrode CE may be a transparent planar electrode. The counter electrode CE may be located on a side of the display medium layer DL opposite to the pixel electrode PE. For example, the counter electrode CE is disposed on the upper substrate TS, and the counter electrode CE is located between the display medium layer DL and the upper substrate TS. The counter electrode CE may be disposed corresponding to the pixel electrode PE. An electric field formed by the pixel electrode PE and the counter electrode CE can drive the display medium molecules DM located in the display area A1 of the display medium layer DL to rotate. In some embodiments, the state of the display medium molecules DM can be changed by the magnitude of the applied electric field and the speed at which the electric field is removed. In some embodiments, one of the counter electrode CE and the transparent electrode TE may be selectively disposed.

The display medium molecules DM of the display medium layer DL may include, for example, positive-type liquid crystal molecules or negative-type liquid crystal molecules. In some embodiments, the display medium molecules DM may include vertical alignment (VA) liquid crystal molecules, twisted nematic (TN) liquid crystal molecules, or in-plane switching (IPS) liquid crystal molecules. In some embodiments, the display medium layer DL in the display unit 110 can provide different levels of transmittance, so that the display unit 110 can provide, for example, different levels of grayscale. In some embodiments, the transmittance of the display medium layer DL is 0% to 95%, for example, about 25%, about 50%, or about 75%.

In some embodiments, the materials of the pixel electrode PE, the transparent electrode TE, and the counter electrode CE each independently include an oxide of a metal material, a nitride of a metal material, a oxynitride of a metal material, or other suitable transparent conductive materials, or a stacked layer of the above transparent conductive materials. For example, indium tin oxide, indium zinc oxide, aluminum tin oxide, aluminum zinc oxide, indium gallium zinc oxide, or a stacked layer of at least two of the above may be used, but are not limited thereto.

In some embodiments, the display panel 100 further includes a backlight module BL located in the display area A1. For example, when the display unit 110 is a non-self-emissive display unit (for example, a liquid crystal display unit), the backlight module BL may be disposed corresponding to the liquid crystal display units in the display area A1 to provide a light source to the liquid crystal display units.

In some embodiments, the display device 10 further includes insulating layers I1, I2, and I3. The insulating layer I1 may be located between the drain DE1 of the transistor T1 and the pixel electrode PE. The insulating layer I1 may also be located between the transparent electrode TE and the lower substrate BS. The insulating layer I2 may be located between a drain DE2 of a transistor T2 and a conductive member 143. The insulating layer I2 may also be located between a wire WR2 and a conductive member 144. The insulating layer I3 may be located between the pixel electrode PE and the drain DE1 of the transistor T1. The insulating layer I3 may also be located between an electrode 141 of a light-emitting element 140 and the conductive member 143. The insulating layer I3 may also be located between an electrode 142 of the light-emitting element 140 and the conductive member 144. The materials of the insulating layers I1, I2, and I3 may include silicon oxide (SiOx), silicon nitride (SiNx), or other suitable materials. In addition, the insulating layers I1, I2, and I3 located in the display area A1 and the insulating layers I1, I2, and I3 located in the display area A2 may respectively belong to the same film layer.

Please refer to FIGS. 3 and 4. In the display area A2, the display panel 100 may include a plurality of display units 120. The display area A2 is, for example, a region where the display units 120 are located, and the display unit 120 may be a sub-pixel in the display area A2 of the display panel 100. In some embodiments, the display unit 120 is a light-emitting diode (LED) display unit, but is not limited thereto. In other embodiments, the display unit 120 may be a display unit using other suitable display technologies. In some embodiments, the display area A1 may display images by means of liquid crystal display, and at the same time, the display area A2 may display images by means of LED. Therefore, the images of the display area A1 and the display area A2 of the display panel 100 can be continuous, so that the display device 10 can achieve a seamless tiled display effect.

Please refer to FIG. 2. In some embodiments, the chip bonding member 131 includes an existing LCD driving chip (for example, chip on film (COF)), and the chip bonding member 132 includes an existing LED driving chip. In this way, the display panel 100 and the display device 10 can simultaneously use two different driving chips to drive two types of display architectures, and each driving chip still has its own color adjustment function (for example, Gamma, demura algorithm, etc.), thereby providing optimized visual effect and optical consistency.

Please refer to FIG. 3. In some embodiments, each display unit 120 may include one or more light-emitting elements 140. The light-emitting element 140 may be disposed on the lower substrate BS. In some embodiments, the light-emitting element 140 is located between the lower substrate BS and the display medium layer DL. The light-emitting element 140 is, for example, a micro light-emitting diode (micro-LED). For example, each display unit 120 may form a sub-pixel in the display area A2 of the display device 10, and each display unit 120 may have a different light color, for example, red, green, or blue, such that three or more display units 120 having different light colors may form a pixel in the display area A2 of the display device 10, thereby achieving full-color display effect of the display area A2. In some embodiments, the display unit 120 further includes a color conversion structure (not shown). The color conversion structure may be disposed between the light-emitting element 140 and the upper substrate TS to further adjust the light color of the display unit 120.

In some embodiments, due to the inherent error of the coating precision of the sealant 130, the sealant 130 may cover the display units 120 located in the middle region of the display area A2, but the sealant 130 may not cover the display units 120 located closest to the display area A1 in the display area A2. For example, the sealant 130 may cover a light-emitting element 140A located in the middle region of the display area A2, but the sealant 130 does not cover a light-emitting element 140B located closest to the display area A1 in the display area A2.

The display panel 100 may further include a circuit structure disposed corresponding to the light-emitting element 140. The circuit structure includes, for example, a transistor T2. The transistor T2 may be disposed on the lower substrate BS. For example, the transistor T2 may be disposed between the lower substrate BS and the sealant 130. A gate G2 of the transistor T2 may receive a gate signal. A source S2 of the transistor T2 may receive a source signal. By controlling the gate signal, the transistor T2 is turned on or off, so that the source signal can be transmitted to an electrode 141 of the light-emitting element 140 through a channel C2 and a drain DE2 of the transistor T2. In some embodiments, the electrode 141 of the light-emitting element 140 is electrically connected to the drain DE2 of the transistor T2 through a conductive member 143.

The material of the channel C2 of the transistor T2 may include, for example, polysilicon or a conductive oxide, but is not limited thereto. The materials of the gate G2, the source S2, and the drain DE2 of the transistor T2 may include opaque conductive materials, for example, molybdenum, aluminum, titanium, copper, gold, silver, or other metals, or alloys of any two or more of the above metals, or other conductive materials, or stacked layers of any two or more of the above conductive materials.

In some embodiments, the display panel 100 further includes a wire WR3 and a signal source PS. The wire WR2 may be electrically connected to the wire WR3. The wire WR3 may be electrically connected to the signal source PS. An electrode 142 of the light-emitting element 140 may be electrically connected to the wire WR2 through a conductive member 144. By controlling the signal transmitted by the signal source PS or the on or off state of the transistor T2, whether the light-emitting element 140 emits light can be controlled. In some embodiments, the signal source PS is a voltage source.

Please refer to FIG. 4. In some embodiments, the display panel 100 further includes a driving element 150. The driving element 150 may be a gate driving element, for example, a gate driver on array (GOA). The driving element 150 may be located in the display area A2 to avoid affecting the aperture ratio of the display area A1.

For example, the display panel 100 includes a plurality of scan lines 112, a plurality of scan lines 122, and a plurality of driving elements 150. The plurality of scan lines 112 may extend substantially parallel to each other along a direction D1 and be arranged along a direction D2 in the display area A1. The direction D2 may intersect the direction D1. In some embodiments, the direction D2 is substantially orthogonal to the direction D1. In addition, the plurality of scan lines 122 may extend substantially parallel to each other along the direction D1 and be arranged along the direction D2 in the display area A2. The plurality of driving elements 150 may be arranged along the direction D2 in the display area A2, and may be respectively disposed corresponding to different rows of the scan lines 112 and/or the scan lines 122. The plurality of scan lines 112 may be electrically connected respectively to corresponding driving elements 150. The plurality of scan lines 122 may be electrically connected respectively to corresponding driving elements 150. In this way, each of the driving elements 150 may provide a gate driving signal to the corresponding scan line 112 and/or scan line 122. In some embodiments, each driving element 150 may simultaneously provide a gate driving signal to the corresponding scan line 112 and the scan line 122.

Please refer to FIGS. 2 and 4 to 6 at the same time. The display panel 100 further includes a plurality of data lines 114 and a plurality of data lines 124. The plurality of data lines 114 may extend substantially parallel to each other along the direction D2 and be arranged along the direction D1 in the display area A1. The plurality of data lines 124 may extend substantially parallel to each other along the direction D2 and be arranged along the direction D1 in the display area A1 and the display area A2. In some embodiments, the sealant 130 covers a portion of the display units 120, a portion of the scan lines 122, and a portion of the data lines 124 in the display area A2.

In some embodiments, the plurality of data lines 114 may respectively fan out from the corresponding chip bonding members 131 to the display area A1. A portion of the plurality of data lines 124 may fan out from the corresponding chip bonding members 132 to the display areas A2 located at the left and right sides of the display area A1, and another portion of the plurality of data lines 124 may fan out to the display area A1 and extend through the display area A1 to the display area A2 located below the display area A1.

The scan lines 112 and the data lines 114 may be electrically connected to the corresponding display units 110, and the scan lines 122 and the data lines 124 may be electrically connected to the corresponding display units 120. In this way, each of the driving elements 150 may provide a scan signal to the corresponding display unit 110 through the corresponding scan line 112, and each of the chip bonding members 131 may provide a data signal to the corresponding display unit 110 through the corresponding data line 114. In addition, each of the driving elements 150 may provide a scan signal to the corresponding display unit 120 through the corresponding scan line 122, and each of the chip bonding members 132 may provide a data signal to the corresponding display unit 120 through the corresponding data line 124.

Please refer to FIGS. 5 and 6. The display unit 110 may include adjacent display units 110A and 110B. The data line 114 may be disposed between the display unit 110A and the display unit 110B, and the data line 124 may be disposed directly above the data line 114. In some embodiments, a wire WR1 that is electrically connected to or in physical contact with the transparent electrode TE may serve as a common electrode line or be electrically connected to a common electrode line (not shown), and the wire WR1 may be disposed directly above the data line 124. In some embodiments, the wire WR1 overlaps the data line 124, and the data line 124 overlaps the data line 114.

A buffer layer BF and an insulating layer IS1 may be disposed between the data line 114 and the lower substrate BS. A planarization layer PL1 and an insulating layer IS2 may be disposed between the data line 124 and the data line 114. A planarization layer PL2 and an insulating layer IS3 may be disposed between the wire WR1 and the data line 124. An insulating layer IS4 may be disposed between the pixel electrode PE and the transparent electrode TE. In some embodiments, the insulating layer IS4 includes the insulating layers I2 and I3 shown in FIG. 3. The materials of the insulating layers IS1 to IS4 may include silicon oxide (SiOx), silicon nitride (SiNx), or other suitable materials. The materials of the planarization layers PL1 and PL2 may include organic insulating materials applicable to ultra-high aperture (UHA) technology, for example, acrylic materials, siloxane materials, polyimide materials, or epoxy materials.

In some embodiments, the display panel 100 further includes a plurality of color filter structures CF and a plurality of black matrix structures BM. The black matrix structures BM may be respectively located between the color filter structures CF. The plurality of black matrix structures BM may respectively overlap the plurality of data lines 114. Alternatively, the plurality of black matrix structures BM may respectively overlap the plurality of data lines 124. Alternatively, the plurality of black matrix structures BM may respectively overlap the plurality of wires WR1. In some embodiments, the color filter structures CF may be disposed only in the display area A1 and not in the display area A2. The color filter structures CF may include, for example, red filter patterns, green filter patterns, and blue filter patterns, and each filter pattern may be disposed corresponding to a display unit 110, such that the color filter structures CF can individually adjust the light color displayed by each of the display units 110. For example, a color filter structure CFa may include a red filter pattern and be disposed corresponding to the display unit 110A, while a color filter structure CFb may include a green filter pattern and be disposed corresponding to the display unit 110B.

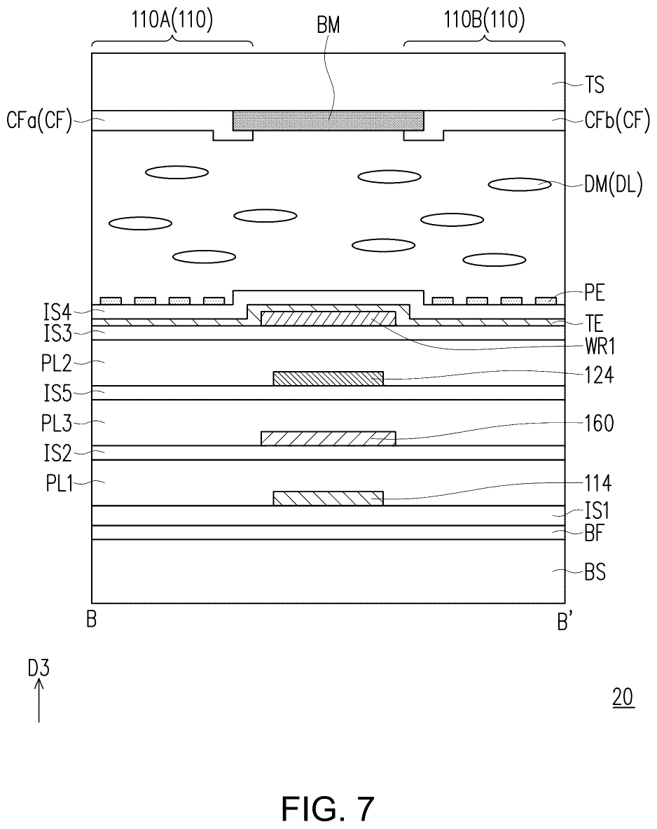

Hereinafter, other embodiments of the disclosure will be described with reference to FIGS. 7 to 9. The same reference numerals and related content used in the embodiments of FIGS. 1 to 6 are used, wherein the same reference numerals are used to indicate the same or similar elements, and the descriptions of the same technical content are omitted. Regarding the omitted descriptions, reference may be made to the embodiments of FIGS. 1 to 6, and repeated descriptions will not be given below.

FIG. 7 is a cross-sectional schematic view of a display device 20 according to an embodiment of the disclosure. Please refer to FIG. 7. The display device 20 may include adjacent display units 110A and 110B, and data lines 114, data lines 124, and a wire WR1 disposed between the display units 110A and 110B.

Compared with the display device 10 shown in FIG. 6, the main difference of the display device 20 shown in FIG. 7 lies in that the display device 20 further includes a shielding line 160. In a direction D3 perpendicular to the lower substrate BS, the shielding line 160 may be located between the data line 114 and the data line 124. The extending direction of the shielding line 160 may be substantially the same as that of the data line 114 or the data line 124. The shielding line 160 may carry a constant voltage signal (for example, a direct current signal). Therefore, the shielding line 160 can shield the data line 114 and the data line 124, so as to avoid the signal carried by the data line 114 and the signal carried by the data line 124 from being coupled during forward scan or reverse scan of the data signal, which would cause a color shift of the light color of the display unit 110 and result in banding in the display area A1.

In some embodiments, the shielding line 160 is a constant voltage signal line for the display unit 110, for example, a common electrode line. Therefore, the shielding line 160 may be located only in the display area A1, and the shielding line 160 may not extend to the display area A2.

In some embodiments, the shielding line 160 is a power signal line for the display unit 120. For example, the shielding line 160 may carry a system reference voltage Vref, a system high voltage VDD, or a system voltage VSS, and the shielding line 160 may extend from the display area A1 to the display area A2. Since the light-emitting element 140 in the display unit 120 requires current when turned on, if the current load is large, an IR drop of VDD or VSS will occur. By providing the power signal directly to the display unit 120 located below the display area A1 through the shielding line 160 passing through the display area A1, the resistance of the power signal line can be reduced, thereby reducing the IR drop.

Please refer to FIG. 5 at the same time. In some embodiments, a shielding line (not shown) overlaps the data line 114, and the shielding line carrying the system high voltage VDD and the shielding line carrying the system voltage VSS may be alternately arranged along the direction D1 between two adjacent display units 110.

In some embodiments, the display device 20 further includes a planarization layer PL3 and an insulating layer IS5 located between the shielding line 160 and the data line 124. The material of the planarization layer PL3 may include organic insulating materials applicable to UHA technology. The insulating layer IS5 may include SiOx, SiNx, or other suitable materials.

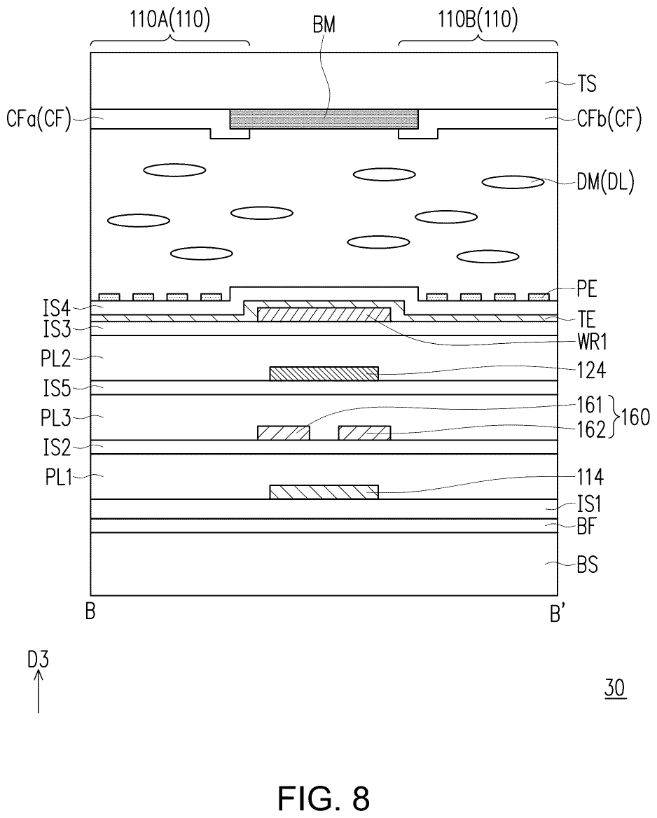

FIG. 8 is a cross-sectional schematic view of a display device 30 according to an embodiment of the disclosure. Please refer to FIG. 8. The display device 30 may include adjacent display units 110A and 110B, and a data line 114, a data line 124, a wire WR1, and a shielding line 160 disposed between the display units 110A and 110B.

Compared with the display device 20 shown in FIG. 7, the main difference of the display device 30 shown in FIG. 8 lies in that the shielding line 160 of the display device 30 includes a shielding line 161 and a shielding line 162 that are physically separated from each other, wherein the shielding line 161 may carry, for example, a system high voltage VDD, and the shielding line 162 may carry, for example, a system voltage VSS.

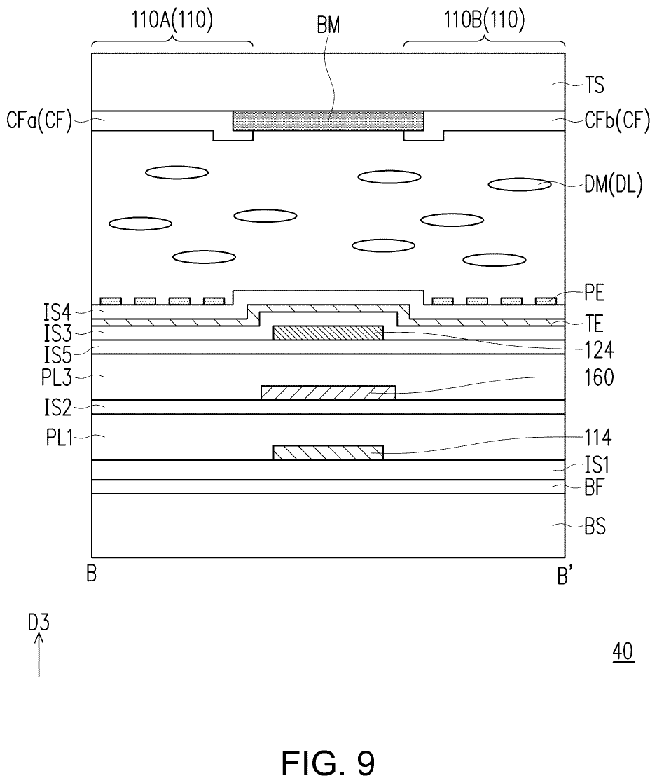

FIG. 9 is a cross-sectional schematic view of a display device 40 according to an embodiment of the disclosure. Please refer to FIG. 9. The display device 40 may include adjacent display units 110A and 110B, and a data line 114, a data line 124, and a shielding line 160 disposed between the display units 110A and 110B.

Compared with the display device 20 shown in FIG. 7, the main difference of the display device 40 shown in FIG. 9 lies in that the display device 40 may not include the wire WR1, and the transparent electrode TE of the display device 40 may be electrically connected to a common electrode line (not shown) through, for example, a via (not shown) passing through the planarization layer PL3 and the insulating layers IS3 and IS5, and a wire belonging to the same film layer as the shielding line 160.

In summary, the display device of the disclosure is capable of achieving a seamless tiled display effect by disposing an LED display unit in the sealant area of the liquid crystal display panel. In addition, the display device of the disclosure is capable of avoiding affecting the aperture ratio of the liquid crystal display area by disposing the gate driving element in the sealant area. Furthermore, the display device of the disclosure is capable of simultaneously using two different existing driving chips (COF) to drive two types of display architectures by allowing the data line electrically connected to the LED display unit to pass through the liquid crystal display area. In addition, the display device of the disclosure may further dispose a constant voltage shielding line between the data line electrically connected to the LED display unit and the data line electrically connected to the liquid crystal display unit, so as to avoid coupling between the two data lines, which may cause color shift in the display image. Moreover, the shielding line may also serve as a power signal line such as a system high voltage VDD, a system voltage VSS, and/or a system reference voltage Vref, so as to reduce the IR drop of the power signal line wired to the LED display unit.

Although the disclosure has been described with reference to the above embodiments, they are not intended to limit the disclosure. It will be apparent to one of ordinary skill in the art that modifications to the described embodiments may be made without departing from the spirit and the scope of the disclosure. Accordingly, the scope of the disclosure will be defined by the attached claims and their equivalents and not by the above detailed descriptions.

What is claimed is:

1. A display panel, having a first display area and a second display area adjacent to the first display area, and comprising:
a plurality of first display units disposed in the first display area;
a first scan line disposed in the first display area and electrically connected to the plurality of first display units;
a first data line disposed in the first display area and electrically connected to the plurality of first display units;
a plurality of second display units disposed in the second display area;
a second scan line disposed in the second display area and electrically connected to the plurality of second display units; and
a second data line disposed in the first display area and the second display area and electrically connected to the plurality of second display units.

2. The display panel according to claim 1, wherein the plurality of first display units are a plurality of liquid crystal display units or a plurality of organic light-emitting diode display units.

3. The display panel according to claim 1, wherein the plurality of second display units are a plurality of micro light-emitting diode display units.

4. The display panel according to claim 1, wherein the display panel comprises a plurality of the first scan lines, the plurality of first scan lines extend along a first direction and are arranged along a second direction, and the second direction intersects the first direction.

5. The display panel according to claim 4, wherein the display panel comprises a plurality of the first data lines, and the plurality of first data lines extend along the second direction and are arranged along the first direction.

6. The display panel according to claim 1, wherein the display panel comprises a plurality of the second scan lines, and the plurality of second scan lines extend along the first direction and are arranged along the second direction.

7. The display panel according to claim 6, wherein the display panel comprises a plurality of the second data lines, and the plurality of second data lines extend along the second direction and are arranged along the first direction.

8. The display panel according to claim 1, further comprising a shielding line disposed between the first data line and the second data line.

9. The display panel according to claim 8, wherein the shielding line is disposed only in the first display area, and the shielding line is a common electrode line for the plurality of first display units.

10. The display panel according to claim 8, wherein the shielding line is disposed in the first display area and the second display area, and the shielding line is a power signal line for the plurality of second display units.

11. The display panel according to claim 10, wherein the power signal line comprises at least one of a system high voltage signal line, a system voltage signal line, and a system reference voltage signal line.

12. The display panel according to claim 11, wherein the power signal line comprises the system high voltage signal line and the system voltage signal line, and the system high voltage signal line and the system voltage signal line are alternately arranged along the first direction.

13. The display panel according to claim 12, wherein the system high voltage signal line and the system voltage signal line overlap a same one of the plurality of first data lines.

14. The display panel according to claim 12, wherein the system high voltage signal line and the system voltage signal line overlap different ones of the plurality of first data lines.

15. The display panel according to claim 1, further comprising a sealant disposed in the second display area and covering a portion of the plurality of second display units.

16. The display panel according to claim 1, further comprising a gate driving element disposed in the second display area and electrically connected to the first scan line and the second scan line.

17. The display panel according to claim 1, further comprising a first chip bonding member and a second chip bonding member disposed in a peripheral area of the display panel and respectively electrically connected to the first data line and the second data line.

18. A tiled display device, comprising:
two adjacent display panels according to claim 1.

19. A vehicle display apparatus, comprising the display panel according to claim 1.

20. The vehicle display apparatus according to claim 19, having a display screen with a strip-shaped or T-shaped profile.
